(19) United States
(12) Patent Application Publication
(10) Pub. No.: US 2006/0137606 A1
(43) Pub. Date: Jun. 29, 2006

(54) High density plasma chemical vapor deposition apparatus for manufacturing semiconductor

(75) Inventor: Soo Jae Lee, Gyunggi-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/052,153

(22) Filed: Feb. 7, 2005

(30) Foreign Application Priority Data
Dec. 29, 2004 (KR) 2004-114737

(51) Int. Cl. C23C 16/00; H01L 21/306

(52) U.S. Cl. 118/715; 156/345.33

(57) ABSTRACT

A high-density plasma CVD apparatus designed to allow an angle of gas injectors to be adjusted according to an etching rate of a chemical mechanical polishing process. The apparatus comprises a deposition chamber constituted by an upper chamber equipped to an upper portion of the deposition chamber and a lower chamber equipped to a lower portion of the deposition chamber, an electrostatic chuck equipped to the lower chamber so as to allow a wafer to be placed thereon and connected to a high frequency power source, a plurality of gas injectors disposed on an inner side surface of the deposition chamber while being uniformly spaced a predetermined distance from each other relative to the horizontal surface for injecting source gas for a CVD process, an angle-adjusting unit for adjusting an angle of the gas injectors, and a controller for controlling operation of the high-density plasma CVD apparatus to adjust the angle of the gas injectors through the angle-adjusting unit.

### BACKGROUND OF THE INVENTION

1. Field of the Invention

The present invention generally relates to an apparatus for manufacturing a semiconductor, and, more particularly, to a high-density plasma chemical vapor deposition (CVD) apparatus for manufacturing a semiconductor.

2. Description of the Related Art

Generally, as a result of high integration of semiconductor devices, requirements for providing more critical dimensions and higher aspect ratio in the structure of an interlayer insulation film and in a device separating process, such as shallow trench isolation (STI) has increased. At this time, materials for the flattening steps created during a process of manufacturing the semiconductor devices include boron phosphorous silicon glass (BPSG) films, un-doped silicon glass (USG) films created by a chemical vapor deposition (CVD) process, high-density plasma CVD films, and the like. A high-density plasma CVD apparatus for manufacturing the high-density plasma CVD film forms the films during a depositing process and an etching process, which are performed simultaneously.

Currently, the most preferred film for gap filling the steps created during the process of manufacturing the semiconductor devices is a film deposited by the high-density plasma CVD apparatus.

FIG. 1 is a diagram illustrating a conventional high-density plasma CVD apparatus.

Referring to FIG. 1, the high-density plasma CVD apparatus 10 comprises a deposition chamber, an electrostatic chuck 40, and a plurality of gas injectors 60.

The deposition chamber comprises an upper chamber 30, and a lower chamber 20. The upper chamber 30 has a dome shape, and is connected to a low frequency power source. The lower chamber 20 is provided with the electrostatic chuck 40 on which a wafer 50 is placed, and the electrostatic chuck 40 is connected to a high frequency power source used for a bias power source.

The plurality of gas injectors 60 are equipped to an inner side surface of the deposition chamber, in such a manner that about 8 to 24 gas injectors 60 are uniformly spaced a predetermined distance from each other along the circumference of the electrostatic chuck 40. Each of the gas injectors 60 injects a certain gas (for example, SiH₄) for the CVD process above the wafer 50 disposed on the electrostatic chuck 40.

In the high-density plasma CVD apparatus 10 constructed as described above, the low frequency power is applied to the upper chamber 30, and the high frequency power is applied to the electrostatic chuck 40. Then, source gas is injected into the chamber through the plurality of gas injectors 60.

The gas injected into the chamber through the plurality of gas injectors 60 becomes plasma by the low frequency power applied to the upper chamber 30. Ions of the plasma are deposited on the surface of the wafer by the high frequency power applied to the electrostatic chuck 40.

FIG. 2 is a diagram illustrating the gas injectors of the conventional high-density plasma CVD apparatus.

As shown in FIG. 2, since the plurality of gas injectors 60 are fixed to the side surfaces of the chamber in a state of being slanted at an angle of 45° relative to the horizontal surface, that is, relative to the electrostatic chuck 40, a portion of the wafer adjacent to the injectors 60 is deposited with a thick insulation film, while the center and the edges of the wafer are deposited with a thin insulation film. In this case, the uniformity in thickness of the insulation film deposited on the wafer by the high-density plasma CVD process becomes worse than that deposited by a PECVD process.

As such, upon deposition of the insulation film by the high-density plasma CVD process, if deposition thickness is not uniform, thereby forming an asymmetrical film on the wafer, a problem of reducing the uniformity in polishing upon a chemical mechanical polishing process is caused.

### SUMMARY OF THE INVENTION

The present invention has been made to solve the above problems, and it is an object of the present invention to provide a high-density plasma CVD apparatus for manufacturing a semiconductor, designed to allow an angle of gas injectors to be adjusted according to an etching rate of a following CMP process, thereby allowing adjustment of thickness of an insulation film deposited on a wafer according to the position on the surface of the wafer.

In accordance with an aspect of the present invention, the above and other objects can be accomplished by the provision of a high-density plasma CVD apparatus for manufacturing a semiconductor, comprising: a deposition chamber constituted by an upper chamber connected to a low frequency power source and a lower chamber; an electrostatic chuck equipped to the lower chamber so as to allow a wafer to be placed thereon and connected to a high frequency power source; a plurality of gas injectors disposed on an inner side surface of the deposition chamber while being uniformly spaced a predetermined distance from each other relative to the horizontal surface for injecting source gas for a CVD process; an angle-adjusting unit for adjusting an angle of the gas injectors; and a controller for controlling operation of the high-density plasma CVD apparatus to adjust the angle of the gas injectors through the angle-adjusting unit.

### BRIEF DESCRIPTION OF THE DRAWINGS

The foregoing and other objects and features of the present invention will be more clearly understood from the following detailed description taken in conjunction with the accompanying drawings, in which:

FIG. 1 is a diagram illustrating a conventional high-density plasma CVD apparatus;

FIG. 2 is a diagram illustrating a plurality of gas injectors of the conventional high-density plasma CVD apparatus;

FIG. 3 is a diagram illustrating a high-density plasma CVD apparatus in accordance with the present invention;

FIG. 4 is a diagram illustrating a plurality of gas injectors of the high-density plasma CVD apparatus in accordance with the present invention; and

FIGS. 5a and 5b are diagrams illustrating the gas injectors of the invention, injection angles of which can be adjusted, and the conventional gas injectors, injection angles which cannot be adjusted, respectively.

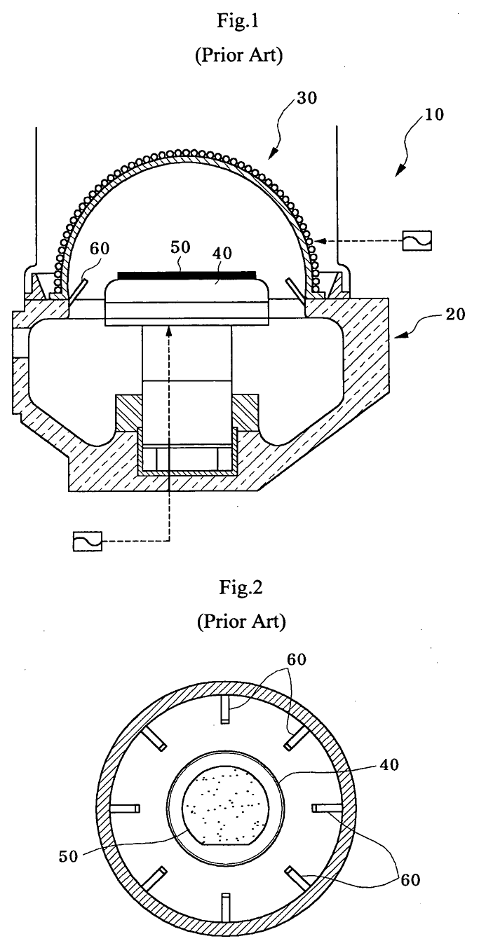

### DESCRIPTION OF THE PREFERRED EMBODIMENTS

Reference will now be made in detail to the embodiments of the present invention with reference to the accompanying drawings, in which components are enlarged for clear description, and like components are denoted by like reference numerals throughout.

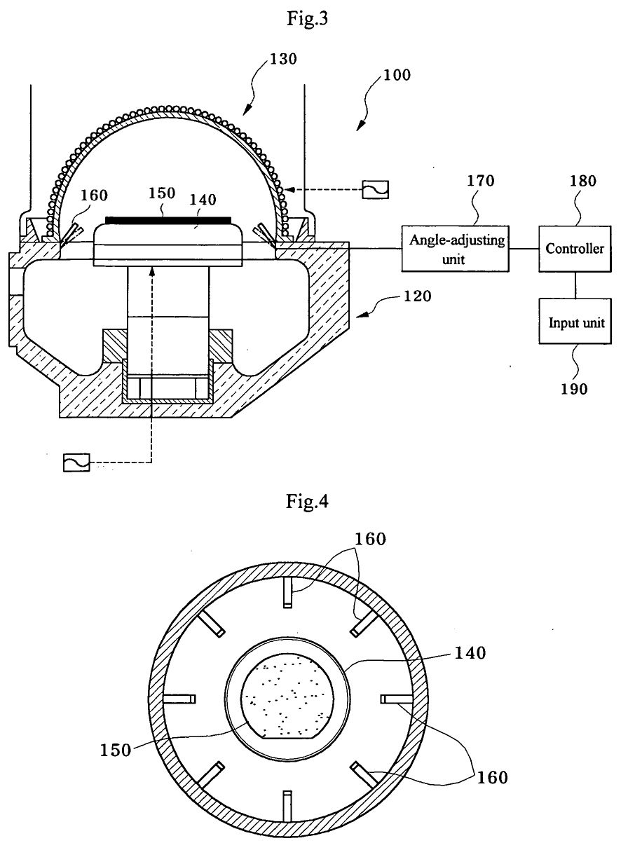

FIG. 3 is a diagram illustrating a high-density plasma CVD apparatus in accordance with the present invention.

Referring to FIG. 3, the high-density plasma CVD apparatus 100 of the invention comprises a deposition chamber, an electrostatic chuck 140, and a plurality of gas injectors 60.

The deposition chamber comprises an upper chamber 130, and a lower chamber 120. The upper chamber 130 has a dome shape, and is connected to a low frequency power source. The lower chamber 120 is provided with the electrostatic chuck 140 on which a wafer 150 is placed, and the electrostatic chuck 140 is connected to a high frequency power source used for a bias power source.

The plurality of gas injectors 160 are equipped to an inner side surface of the deposition chamber in such a manner that about 8 to 24 gas injectors 160 are uniformly spaced a predetermined distance from each other along the circumference of the electrostatic chuck 140. Each of the gas injectors 160 injects a certain gas (for example, SiH₄) for the CVD process above the wafer 150 disposed on the electrostatic chuck 140.

An angle of the plurality of gas injectors 160 of the invention is adjusted in the range of 0˜90° relative to the horizontal surface, that is, relative to the surface of the electrostatic chuck 140.

For this purpose, the high-density plasma CVD apparatus 100 of the invention further comprises an angle-adjusting unit 170 for adjusting the angle of the gas injectors 160. For example, the angle of the gas injectors may be adjusted by means of a stepping motor.

Additionally, the high-density plasma CVD apparatus 100 of the invention comprises a controller, which drives the angle-adjusting unit 170 according to operation signals and control commands for the deposition process inputted through an input unit 190, adjusting the angle of the gas injectors 160 below 45° or to 45° or more, and which applies driving powers to the upper and lower chambers 130 and 120, respectively, controlling the deposition process of the high-density plasma CVD apparatus 100.

If the controller 180 adjusts the angle-adjusting unit 170 according to an input value or a predetermined value inputted from the input unit 190, and lowers the angle of the gas injectors 160 below 45°, an insulation film can be thinly deposited on the central surface of the wafer 150. On the other hand, if the controller 180 adjusts the angle-adjusting unit 170 and raises the angle of the gas injectors 160 to 45° or more, the insulation film can be thickly formed on the central surface of the wafer 150.

According to the present invention, the angle of the gas injectors can be changed according to an etching rate of a following chemical mechanical polishing (CMP) process, thereby allowing adjustment of thickness profile of the insulation film deposited on the wafer.

Operations of the high-density plasma CVD apparatus 100 will be described hereinafter.

The controller 180 applies low frequency power to the upper chamber 130, and high frequency power to the electrostatic chuck 140.

At the same time, the controller 180 drives the angle-adjusting unit 170 according to an input value or a predetermined value inputted from the input unit 190.

With adjustment of the angle-adjusting unit 170, an angle of the gas injectors 160 is lowered below 45°.

As a result, a source gas (for example, SiH₄) for the CVD process is injected to the interior of the chamber through the gas injectors 160, the angle of which is lowered below 45°.

Then, the gas injected to the interior of the chamber through the gas injectors 160 by the low frequency power applied to the upper chamber 130 is transferred to the plasma, and ions of the plasma are deposited on the surface of the wafer by the high frequency power applied to the electrostatic chuck 140. At this time, since the angle of the gas injectors 160 is adjusted below 45°, a deposition film on the center of the wafer 150 has little thickness.

If the controller 180 adjusts the angle-adjusting unit 170 and raises the angle of the gas injectors 160 to 45° or more, the source gas is injected to the interior of the chamber through the gas injectors 160, the angle of which is raised to 45° or more, so that the insulation film on the central surface of the wafer 150 has a higher thickness.

FIG. 4 shows the plurality of gas injectors of the high-density plasma CVD apparatus of the invention.

As shown in FIG. 4, since the angle of the gas injectors 160 is adjusted in the range of 0˜90° relative to the horizontal surface, that is, relative to the surface of the electrostatic chuck 140, the deposition thickness can be adjusted according to the thickness profile of the deposition film required for the CMP process.

Moreover, according to the invention, the gas injectors 160 on the inner side surface of the deposition chamber can be adjusted to have different angles from each other, thereby allowing adjustment of the thickness of the deposition film on the wafer regardless of positions on the wafer.

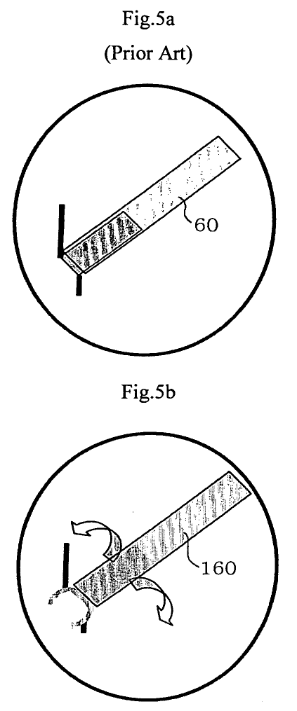

FIGS. 5a and 5b are diagrams illustrating the gas injectors of the invention, injection angles of which can be adjusted, and the conventional gas injectors, injection angles of which cannot be adjusted.

As shown in FIG. 5a, the angle of the conventional gas injectors is fixed to 45°. However, as shown in FIG. 5b, the angle of the gas injectors according to the invention is adjustable in the range of 0˜90°, and thus the angle of the gas injected into the chamber can be changed.

As apparent from the above description, according to the present invention, the angle of the gas injectors can be adjusted according to the etching rate of the following CMP process, thereby allowing adjustment of thickness of the insulation film deposited on the wafer.

Furthermore, the gas injectors can be adjusted to have different angles from each other, thereby allowing adjustment of the thickness of the deposition film on the wafer regardless of positions on the wafer.

It should be understood that the embodiments and the accompanying drawings as described above have been described for illustrative purposes and the present invention is limited by the following claims. Further, those skilled in the art will appreciate that various modifications, additions and substitutions are allowed without departing from the scope and spirit of the invention as set forth in the accompanying claims.

What is claimed is:

1. A high-density plasma CVD apparatus for manufacturing a semiconductor, comprising:
a deposition chamber constituted by an upper chamber connected to a low frequency power source, and a lower chamber;
an electrostatic chuck equipped to the lower chamber so as to allow a wafer to be placed thereon and connected to a high frequency power source;
a plurality of gas injectors disposed on an inner side surface of the deposition chamber while being uniformly spaced a predetermined distance from each other relative to the horizontal surface for injecting source gas for a CVD process;
an angle-adjusting unit for adjusting an angle of the gas injectors; and
a controller for controlling operation of the high-density plasma CVD apparatus to adjust the angle of the gas injectors through the angle-adjusting unit.

2. The apparatus as set forth in claim 1, wherein the controller controls the angle-adjusting unit to allow the plurality of gas injectors to have identical angles.

3. The apparatus as set forth in claim 1, wherein the controller controls the angle-adjusting unit to allow the plurality of gas injectors to have different angles from each other.

4. The apparatus as set forth in claim 1, wherein the angle-adjusting unit adjusts the angle of the plurality of gas injectors in the range of 0˜90°.

5. The apparatus as set forth in claim 1, wherein the controller controls the angle-adjusting unit to increase the angle of the gas injectors to 45° or more in order to increase the thickness of a deposition film at the center of the wafer.

6. The apparatus as set forth in claim 1, wherein the controller controls the angle-adjusting unit to lower the angle of the gas injectors below 45° in order to decrease the thickness of a deposition film at the center of the wafer.
